(19) United States
(12) Patent Application Publication
(10) Pub. No.: US 2009/0161406 A1
(43) Pub. Date: Jun. 25, 2009

(54) NON-VOLATILE MEMORY AND METHOD FOR FABRICATING THE SAME

(75) Inventors: Jen-Chi Chuang, Hsinchu (TW); Chiu-Tsung Huang, Hsinchu (TW); Yu-Chieh Liao, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Powerchip Semiconductor Corp., Hsinchu (TW)

(21) Appl. No.: 12/054,393

(22) Filed: Mar. 25, 2008

(30) Foreign Application Priority Data
Dec. 24, 2007 (TW) 96149685

(51) Int. Cl. G11C 11/36; H01L 21/06; G11C 11/00

(52) U.S. Cl. 365/148; 365/175; 438/102; 365/163; 257/E21.068

(57) ABSTRACT

A non-volatile memory including a diode and a memory cell is described. The diode includes a doped region, a metal silicide layer, and a patterned doped semiconductor layer. The doped region of a first conductive type is formed in a substrate. The metal silicide layer is formed on the substrate. The patterned doped semiconductor layer of a second conductive type is formed on the metal silicide layer. The memory cell is formed on the substrate and coupled with the diode.

### CROSS-REFERENCE TO RELATED APPLICATION

This application claims the priority benefit of Taiwan application serial no. 96149685, filed on Dec. 24, 2007. The entirety the above-mentioned patent application is hereby incorporated by reference herein and made a part of specification.

### BACKGROUND OF THE INVENTION

1. Field of the Invention

The present invention relates to a semiconductor device and a method for fabricating the semiconductor device, and more particularly, to a non-volatile memory and a method for fabricating the non-volatile memory.

2. Description of Related Art

With the popularization of consumer electronics and wide application of system products, memories with low power consumption, low cost, high access speed, small size and high capacity density is increasingly demanded. Among current types of memories, resistive random access memory (RRAM) is one type of non-volatile memory, which the industry is making every effort to develop. RRAM can record data by changing resistivity of a variable resistance layer.

RRAM changes the thin film state of the variable resistance layer by applying current pulse and conversion voltage, such that the state can be changed between a set state and a reset state among different states based on different resistivity. This type of memory has both advantages of static random access memory, e.g., high speed, and dynamic random access memory, e.g., high density, low cost, low power consumption and non-volatility.

FIG. 1 is a cross-sectional view of a conventional resistive memory. The memory illustrated in FIG. 1 is a resistive memory 100 with a diode 120 structure. The resistive memory 100 includes at least a bottom electrode 108, a PrCaMnO (PCMO) layer 110 and a top electrode 112. Both the top electrode 112 and the bottom electrode 108 are platinum electrodes. The bottom electrode 108 is formed on a P-type heavily-doped region 106 that is formed in a P-type silicon substrate 102. The top electrode 112 is formed on the bottom electrode 108. The PrCaMnO layer 110 is formed between the top electrode 112 and the bottom electrode 108, and contacts with each of the top electrode 112 and the bottom electrode 108. In addition, an N-type well region 104 is formed in the P-type silicon substrate 102, and the P-type heavily-doped region 106 is formed in the N-type well region 104. A diode 120 is thus formed at a contact interface between the P-type heavily-doped region 106 and the N-type well region 104 because of the difference in the conductive type of the two materials.

In general, forming the P-type heavily-doped region 106 usually involves an ion implanting process to implant dopant into the N-type well region 104 and a subsequent annealing process after the ion implantation. During the annealing process, however, the profile of the P-type heavily-doped region 106 can often be changed due to an inappropriate thermal treatment, causing two adjacent P-type heavily-doped regions 106 to be electrically connected to each other and form a short circuit therebetween. Moreover, with the rapid advance of the semiconductor fabrication technology, the problem mentioned above should gain more attention as increasingly higher element integrity is required.

### SUMMARY OF THE INVENTION

The present invention is directed to a non-volatile memory that has high integrity, low resistivity and high turn-on current.

The present invention is also directed to a method for fabricating a non-volatile memory which can form self-aligned diode structures so as to form high density memories.

The present invention provides a non-volatile memory including a diode and a memory cell. The diode includes a doped region, a metal silicide layer and a patterned doped semiconductor layer. The doped region is formed in a substrate and of a first conductive type. The metal silicide layer is formed on the substrate. The patterned doped semiconductor layer is formed on the metal silicide layer and of a second conductive type. The memory cell is formed on the substrate and coupled with the diode.

According to one embodiment of the present invention, the material of the metal silicide layer includes TiSi₂, CoSi₂, WSi₂, or NiSi₂.

According to one embodiment of the present invention, the memory cell is a phase change memory (PCM) cell or a resistive memory cell.

According to one embodiment of the present invention, the memory cell includes a top electrode, a bottom electrode coupled with the patterned doped semiconductor layer, and a variable resistance layer formed between the top electrode and the bottom electrode.

According to one embodiment of the present invention, the material of the variable resistance layer includes a chalcogenide or a metal oxide.

According to one embodiment of the present invention, the chalcogenide includes GeSbTe (GST).

According to one embodiment of the present invention, the memory cell further includes a heater electrode formed between the bottom electrode and the variable resistance layer.

According to one embodiment of the present invention, the non-volatile memory further includes a top electrode connector (TEC) and a word line. The top electrode connector is formed on the memory cell and coupled with the top electrode. The word line is formed on the memory cell and coupled with the top electrode connector.

According to one embodiment of the present invention, the non-volatile memory further includes a well region formed in the substrate such that the doped region is located in the well region. The substrate is, for example, of the first conductive type, and the well region is, for example, of the second conductive type.

According to one embodiment of the present invention, the substrate is, for example, of the second conductive type.

According to one embodiment of the present invention, the material of the patterned doped semiconductor layer is, for example, doped polysilicon.

The present invention also provides a method for fabricating a non-volatile memory. A substrate is provided, and a doped region of a first conductive type is then formed in the substrate. A metal silicide layer is formed on the substrate, and subsequently a patterned doped semiconductor layer of a second conductive type is formed on the metal silicide layer. Afterwards, a memory cell is formed on the substrate, and the memory cell is coupled with the patterned doped semiconductor layer.

According to one embodiment of the present invention, the material of the metal silicide layer includes TiSi₂, CoSi₂, WSi₂, or NiSi₂.

According to one embodiment of the present invention, the memory cell is a phase change memory cell or a resistive memory cell.

According to one embodiment of the present invention, forming the memory cell includes, for example, forming a bottom electrode coupled with the patterned doped semiconductor layer on the substrate, forming a variable resistance layer on the bottom electrode, and forming a top electrode on the variable resistance layer.

According to one embodiment of the present invention, the variable resistance layer is formed of one of a chalcogenide and a metal oxide.

According to one embodiment of the present invention, the chalcogenide includes GeSbTe.

According to one embodiment of the present invention, the method further includes forming a heater electrode between the bottom electrode and the variable resistance layer.

According to one embodiment of the present invention, after the top electrode is formed, the method further includes: forming a top electrode connector coupled with the top electrode on the memory cell; and forming a word line coupled with the top electrode connector.

According to one embodiment of the present invention, the method further includes forming a well region in the substrate such that the doped region is located in the well region. The substrate is, for example, of the first conductive type, and the well region is, for example, of the second conductive type.

According to one embodiment of the present invention, the substrate is, for example, of the second conductive type.

According to one embodiment of the present invention, the material of the patterned doped semiconductor layer is, for example, doped polysilicon.

In the non-volatile memory according to the present invention, the diode collectively formed by the doped region, metal silicide layer and patterned doped semiconductor layer has a vertical structure, and the contact interface between the metal silicide layer and the doped region, and the contact interface between the metal silicide layer and the patterned doped semiconductor layer have different contact characteristics. Therefore, the contact resistance can be reduced and the element performance can be enhanced.

In addition, in the method for fabricating a non-volatile memory, the patterned doped semiconductor layer is formed on the metal silicide layer, thus making it possible to form a vertically-structured diode in a self-aligned manner, and form high density memories.

In order to make the aforementioned and other features and advantages of the present invention more comprehensible, embodiments accompanied with figures are described in detail below.

### BRIEF DESCRIPTION OF THE DRAWINGS

FIG. 1 is a cross-sectional view of a conventional resistive memory.

FIGS. 2A through 2D are, cross-sectional views illustrating the fabrication process of a non-volatile memory according to one embodiment of the present invention.

FIG. 3 is a cross-sectional view of a non-volatile memory according to one embodiment of the present invention.

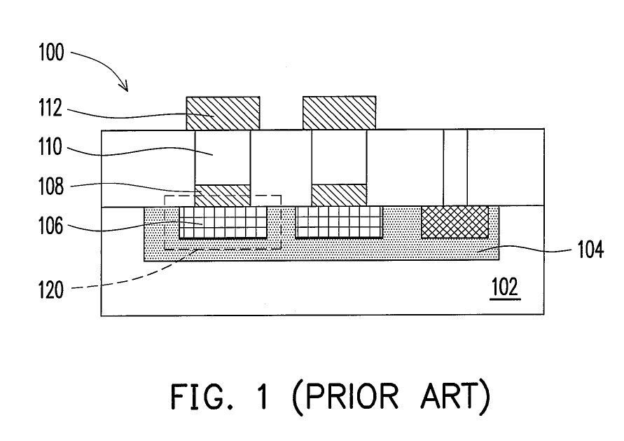

### DESCRIPTION OF THE EMBODIMENTS

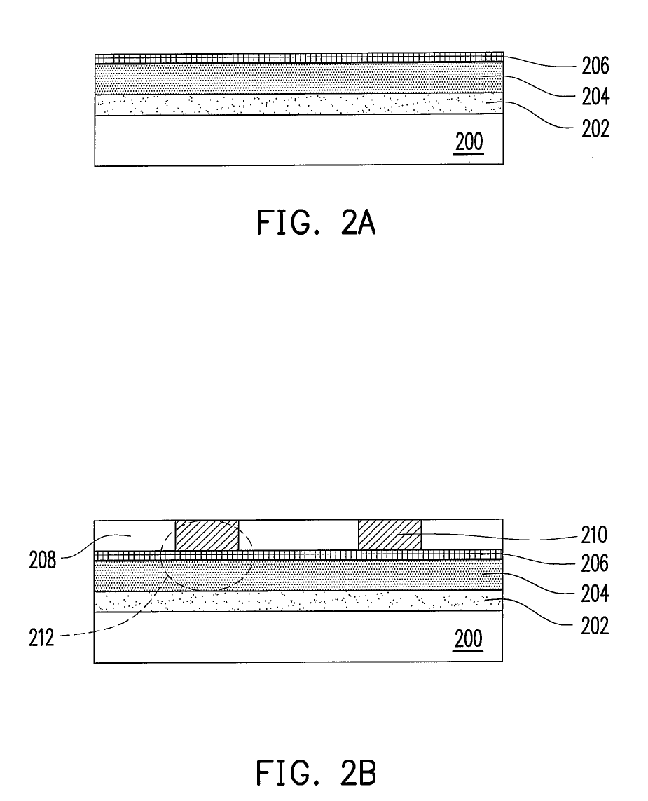

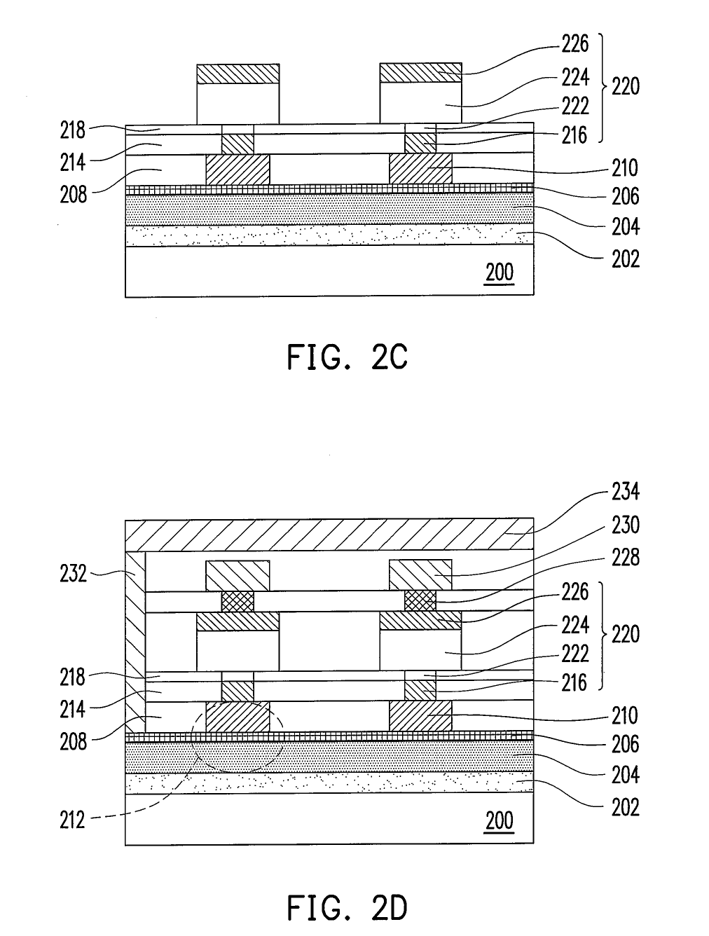

FIGS. 2A through 2D are cross-sectional views illustrating the fabrication process of a non-volatile memory according to one embodiment of the present invention. It is to be understood that the following method for fabricating the non-volatile memory, which forms only one of various types of non-volatile memories, is mainly used to describe the process of forming the diode by the present method such that those skilled in the art can be enabled to practice the present method, and, therefore, should not be used to limit the scope of the present invention. It will be appreciated by those skilled in the art that other elements, such as memory cells, word lines or bit lines, can be otherwise formed and arranged according to known techniques in addition to the arrangement provided by the illustrated embodiment.

Referring to FIG. 2A, a substrate 200 is provided. The substrate 200 is, for example, a P-type silicon substrate. A well region 202 is formed in the substrate 200. The well region 202 is, for example, an N-type well region. The well region 202 may be formed, for example, by performing an ion implanting process to the substrate 200. Then, a doped region 204 is formed in the substrate 200, and specifically in the well region 202. The doped region 204 is, for example, a P-type heavily-doped region, and may be formed by performing an ion implanting process to the substrate 200. In an alternative embodiment, the substrate may be provided with no well regions. In such case, the substrate is, for example, an N-type silicon substrate, and the doped region is a P-type heavily-doped region correspondingly.

As also shown in FIG. 2A, a metal silicide layer 206 is formed on the substrate 200. The metal silicide layer 206 may be formed of TiSi₂, CoSi₂, WSi₂, NiSi₂ or any other suitable metal silicide materials, and may be formed by, for example, physical vapour deposition (PVD) or chemical vapour deposition (CVD).

Referring to FIG. 2B, a patterned doped semiconductor layer 210 is formed on the metal silicide layer 206, and a dielectric layer 208 is formed to cover the portion of the metal silicide layer 206 exposed via the patterned doped semiconductor layer 210. The patterned doped semiconductor layer 210 may be formed of ion-implanted or doped polysilicon, and specifically, of N-type heavily-doped polysilicon. The patterned doped semiconductor layer 210 may be formed as follows. A dielectric layer 208 and a patterned photoresist layer (not shown) are first formed on the substrate 200 in sequence. The patterned photoresist layer is used as a mask to remove an exposed portion of the dielectric layer 208, thereby forming a plurality of openings through which the metal silicide layer 206 is exposed. After the patterned photoresist layer is removed, a doped polysilicon material is filled into the openings, thereby achieving the patterned doped semiconductor layer 210. In an alternative embodiment of forming the patterned doped semiconductor layer 210, a layer of doped polysilicon material may be directly deposited on the metal silicide layer 206. The doped polysilicon layer may then be directly subjected to processes of photolithography and etching to define the patterned doped semiconductor layer 210.

It is noted that a vertically-structured diode 212 is collectively formed by the doped region 204 disposed in the substrate 200, the patterned doped semiconductor layer 210 disposed on the substrate 200, and the metal silicide layer 206 interposed between the doped region 204 and the patterned doped semiconductor layer 210. This arrangement can improve the element density, which facilitates achieving high density memory. Because the metal silicide layer 206 formed of metal silicide material, and the doped region 204 and the patterned doped semiconductor layer 210 formed of semiconductor material each has a different work function, when the metal silicide layer 206 is in contact with the doped region 204 or with the patterned doped semiconductor layer 210, Ohmic contact or a Schottky diode will be formed at a contact interface therebetween depending upon the conductive type (P- or N-type) of the semiconductor material. As shown in FIG. 2B, in the diode 212, Ohmic contact is formed at the interface between the metal silicide layer 206 and the P-type doped region 204, such that contact resistance can be reduced; on the other hand, a Schottky diode is formed at the contact interface between the metal silicide layer 206 and the N-type patterned doped semiconductor layer 210, such that the performance of the diode 212 can be enhanced.

In the above illustrated exemplary embodiment, the diode 212 is formed by forming the P-type doped region 204 in the N-type well region 202 and forming the N-type patterned doped semiconductor layer 210 on the metal silicide layer 206. However, it is noted that the present invention is not limited to this particular embodiment in regard to the forming of the diode. Rather, in alternative embodiments, the arrangement of the conductive type of the substrate 200, the well region 202, the doped region 204, and the patterned doped semiconductor layer 210 could have other combinations to meet the requirements of specific fabrication processes, as long as Ohmic contact is formed at the contact interface between the metal silicide layer 206 and the doped region 204, and a Schottky diode is formed at the contact interface between the metal silicide layer 206 and the patterned doped semiconductor layer 210.

Referring to FIG. 2C, a memory cell 220 is formed on the substrate 200. The memory cell 220 may be a phase change memory cell, a resistive memory cell or other types of memory cell, for example. In one embodiment, the memory cell 220 includes a bottom electrode 216, a variable resistance layer 224, and a top electrode 226. The variable resistance layer 224 is material which will change phase at different temperatures, or change its resistivity in different states. The bottom electrode 216 is formed on the patterned doped semiconductor layer 210, and, therefore, the memory cell 220 can be electrically coupled to the patterned doped semiconductor layer 210.

Take phase change memory cell for example, the memory cell 220 can be formed by the following steps. A dielectric layer 214 is formed over the dielectric layer 208 and the patterned doped semiconductor layer 210, and a bottom electrode 216 is formed in the dielectric layer 214. The bottom electrode 216 may be formed of, for example, metal or other suitable conductive materials. Another dielectric layer 218 is then formed over the dielectric layer 214 and the bottom electrode 216, and an opening (not shown) is formed through the dielectric layer 218 to expose the bottom electrode 216. A heater electrode 222, formed of tungsten, for example, is formed to fill in the opening. Afterwards, a variable resistance material layer (not shown) and a top electrode material layer (not shown) are formed over the dielectric layer 218 and the heater electrodes 222 in that order. The variable resistance material layer may be formed of, for example, chalcogenide. The chalcogenide may be an alloy of germanium, antimony and tellurium, and also referred to as GeSbTe (GST). Alternatively, the chalcogenide may be AgInSbTe, AlAsTe, or other compounds including any chemical elements of group VI in the periodic table. The top electrode material layer may be formed of, for example, metal or other suitable conductive materials. Subsequently, the variable resistance material layer and the top electrode material layer are patterned to form the variable resistance layer 224 and the top electrode 226 on the heater electrode 222.

In the phase change memory cell mentioned above, the heater electrode 222 disposed between the bottom electrode 216 and the variable resistance layer 224 can heat the variable resistance layer 224 to have the chalcogenide of the variable resistance layer 224 switch between two states, a crystalline phase and an amorphous phase. At a high temperature (e.g., over 600° C.), the chalcogenide becomes a liquid. Once cooled, it is solidified into an amorphous glassy phase and has a high electrical resistance. On the other hand, when the chalcogenide is heated to a temperature between its crystallization point and melting point, it transforms into a crystalline phase in which atoms are arranged in a regularly ordered and it has a much lower resistance. As such, by using the characteristic of the chalcogenide that it has different resistance at different temperatures, the basis of data recording performed by the memory cell 220 can be achieved according to resistance of the chalcogenide..

Referring to FIG. 2D, a top electrode connector (TEC) 228 and a word line 230 are formed on the substrate 200. The TEC 228 may be formed of conductive material. The TEC 228 is connected with the top electrode 226 of the memory cell 220, for example. The word line 230 is connected with the TEC 228, for example. As such, the memory cell 220 can be electrically connected to the word line 230 through the TEC 228. Thereafter, a bit line 234 and a contact window 232 connecting the metal silicide layer 206 to the bit line 234 are formed on the substrate 200, and the non-volatile memory of the present invention is thus accomplished.

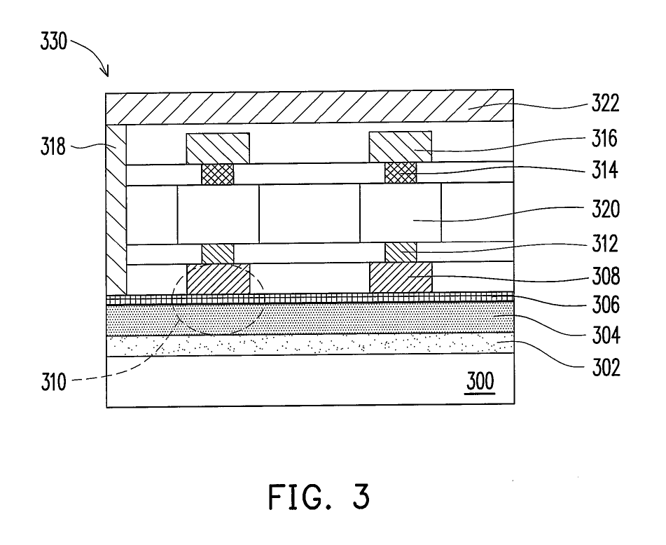

FIG. 3 is a cross-sectional view of a non-volatile memory according to one embodiment of the present invention.

Referring to FIG. 3, the non-volatile memory 330 includes a diode 310 and a memory cell 320. The memory cell 320 is disposed on a substrate 300 and coupled with the diode 310.

The diode 310 includes a doped region 304, a metal silicide layer 306 and a patterned doped semiconductor layer 308. The doped region 304 is of a first conductive type and is, for example, formed in a well region 302 of a substrate 310. In this illustrative embodiment, the substrate 300 is a P-type silicon substrate, the well region 302 is an N-type well region, and the doped region 304 is a P-type heavily-doped region. A metal silicide layer 306 is formed on the doped region 304. The metal silicide layer 306 may be formed of TiSi2, CoSi2, WSi2, NiSi2 or any other suitable metal silicide materials. The patterned doped semiconductor layer 308 of a second conductive type is formed on the metal silicide layer 306. The patterned doped semiconductor layer 308 may be formed of doped polysilicon. In this illustrative embodiment, corresponding to the P-type heavily-doped region 304, the patterned doped semiconductor layer 308 is formed of N-type heavily-doped polysilicon.

The memory cell 320 may be a phase change memory cell, a resistive memory cell or any other types of memory cell. The memory cell 320 is connected with the patterned doped semiconductor layer 308 of the diode 310 through, for example, a conductive layer 312. In one embodiment, the memory cell 320 includes a top electrode (not shown), a bottom electrode (not shown) coupled with the patterned doped semiconductor layer 308, and a variable resistance layer (not shown) formed between the top electrode and the bottom electrode. The variable resistance layer may be formed of a chalcogenide or a metal oxide. For example, the chalcogenide of the phase change memory cell may be an alloy of germanium, antimony and tellurium, and also referred to as GeSbTe (GST). In the case of the phase change memory cell, the memory cell further includes a heater electrode formed between the bottom electrode and the variable resistance layer, for heating the variable resistance layer. By heating the variable resistance layer with various temperatures, the chalcogenide of the variable resistance layer can repeatedly switch between a crystalline phase and an amorphous phase, thereby producing different resistivity to realize memory function. Of course, in another embodiment, the memory cell 320 may also be of another type, and thus it is to be understood the memory cell 320 should not be limited to any particular type according to the present invention.

In addition, the non-volatile memory 330 further includes a word line 316 and a bit line 322 formed on the memory cell 320. The word line 316 is electrically connected to the memory cell 320 through, for example, a conductive layer 314. The bit line 322 is electrically connected to the metal silicide layer 306 through, for example, a contact window 318. In one embodiment, when the memory cell 320 is a phase change memory cell or a resistive memory cell, the conductive layer 314 may be a top electrode connector for coupling the top electrode of the memory cell 320 to the word line 316.

It should be noted that the diode 310 collectively formed by the doped region 304, the metal silicide layer 306 and the patterned doped semiconductor layer 308 is perpendicular to a surface of the substrate 300, such that element integrity can be improved. In addition, the metal silicide layer 306 is formed of a metal silicide material, and both the doped region 304 and patterned doped semiconductor layer 308 are formed of semiconductor materials. Because of the difference in material characteristics of the metal silicide material and the semiconductor material, the interface between two different kinds of materials provides a special interface characteristic. For example, Ohmic contact is formed at the interface between the metal silicide layer 306 and the P-type doped region 304, which diminishes the contact resistance and thus reduces the resistivity. On the other hand, a Schottky diode is formed at the interface between the metal silicide layer 306 and the N-type patterned doped semiconductor layer 308, which has a lower forward voltage drop and thus enhances the element performance.

In the above described exemplary embodiment, the diode of the non-volatile memory is illustrated in which a P-type doped region 304 and a N-type patterned doped semiconductor layer 308 are disposed on opposite two sides of a metal silicide layer 306, respectively. It is to be understood that the present invention is not limited to this particular construction. Rather, in alternative embodiments, the arrangement of the conductive type of the substrate 300, the well region 302, the doped region 304, and the patterned doped semiconductor layer 308 could have other combinations, as long as Ohmic contact is formed at the contact interface between the metal silicide layer 306 and the doped region 304, and a Schottky diode is formed at the contact interface between the metal silicide layer 306 and the patterned doped semiconductor layer 308. Of course, in other embodiments, to meet the requirements of specific fabrication processes, a doped region may be directly formed in the substrate without forming the well region.

In summary, the non-volatile memory and its fabrication method according to the present invention have at least the following advantages:

1. In the non-volatile memory and its fabrication method according to the present invention, the diode structure is formed by disposing two semiconductors of different conductive types on top and bottom sides of a metal silicide layer so as to form Ohmic contact and a Schottky diode at top and bottom contact interfaces, respectively. Thus, resistivity can be reduced and element performance can be enhanced effectively.

2. In the non-volatile memory and its fabrication method according to the present invention, the diode structure is perpendicular to a surface of the substrate, i.e. the diode is forms at the contact interface between the patterned doped semiconductor layer and the metal silicide layer. Therefore, the present invention can form self-aligned diode structures and high density memories.

3. The non-volatile memory of the present invention can be fabricated through a simple process and has a simplified circuit design, thus reducing the fabrication cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory comprising:
a diode comprising:
a doped region of a first conductive type formed in a substrate;
a metal silicide layer formed on the substrate;
a patterned doped semiconductor layer of a second conductive type formed on the metal silicide layer; and
a memory cell formed on the substrate and coupled with the diode.

2. The non-volatile memory in accordance with claim 1, wherein the material of the metal silicide layer comprises TiSi₂, CoSi₂, WSi₂, or NiSi₂.

3. The non-volatile memory in accordance with claim 1, wherein the memory cell is a phase change memory cell or a resistive memory cell.

4. The non-volatile memory in accordance with claim 3, wherein the memory cell comprises:
a top electrode;
a bottom electrode coupled with the patterned doped semiconductor layer; and
a variable resistance layer formed between the top electrode and the bottom electrode.

5. The non-volatile memory in accordance with claim 4, wherein the material of the variable resistance layer comprises a chalcogenide or a metal oxide.

6. The non-volatile memory in accordance with claim 5, wherein the chalcogenide comprises GeSbTe.

7. The non-volatile memory in accordance with claim 4, wherein the memory cell further comprises a heater electrode formed between the bottom electrode and the variable resistance layer.

8. The non-volatile memory in accordance with claim 4, further comprising:
a top electrode connector formed on the memory cell and coupled with the top electrode; and
a word line formed on the memory cell and coupled with the top electrode connector.

9. The non-volatile memory in accordance with claim 1, further comprising a well region formed in the substrate such that the doped region is located in the well region, wherein the substrate is of the first conductive type, and the well region is of the second conductive type.

10. The non-volatile memory in accordance with claim 1, wherein the substrate is of the second conductive type.

11. The non-volatile memory in accordance with claim 1, wherein the material of the patterned doped semiconductor layer is doped polysilicon.

12. A method for fabricating a non-volatile memory, comprising:
providing a substrate;
forming a doped region of a first conductive type in the substrate;
forming a metal silicide layer on the substrate;
forming a patterned doped semiconductor layer of a second conductive type on the metal silicide layer; and
forming a memory cell on the substrate, wherein the memory cell is coupled with the patterned doped semiconductor layer.

13. The method in accordance with claim 12, wherein the material of the metal silicide layer comprises TiSi₂, CoSi₂, WSi₂, or NiSi₂.

14. The method in accordance with claim 12, wherein the memory cell is a phase change memory cell or a resistive memory cell.

15. The method in accordance with claim 14, wherein forming the memory cell comprises:
forming a bottom electrode on the substrate, wherein the bottom electrode is coupled with the patterned doped semiconductor layer;
forming a variable resistance layer on the bottom electrode; and
forming a top electrode on the variable resistance layer.

16. The method in accordance with claim 15, wherein the material of the variable resistance layer comprises a chalcogenide or a metal oxide.

17. The method in accordance with claim 16, wherein the chalcogenide comprises GeSbTe.

18. The method in accordance with claim 15, further comprising forming a heater electrode between the bottom electrode and the variable resistance layer.

19. The method in accordance with claim 15, after the top electrode is formed, further comprising:
forming a top electrode connector coupled with the top electrode on the memory cell; and
forming a word line coupled with the top electrode connector.

20. The method in accordance with claim 12, further comprising forming a well region in the substrate such that the doped region is located in the well region, wherein the substrate is of the first conductive type, and the well region is of the second conductive type.

21. The method in accordance with claim 12, wherein the substrate is of the second conductive type.

22. The method in accordance with claim 12, wherein the material of the patterned doped semiconductor layer is doped polysilicon.
